(19) United States
(12) Patent Application Publication
(10) Pub. No.: US 2012/0129333 A1
(43) Pub. Date: May 24, 2012

(54) METHOD FOR MANUFACTURING SEMICONDUCTOR PACKAGE AND SEMICONDUCTOR PACKAGE MANUFACTURED USING THE SAME

(75) Inventors: Ha-Young YIM, Seoul (KR); Eun-Chul AHN, Yongin-si (KR); Ui-Hyoung LEE, Seoul (KR); Moon-Gi CHO, Suwon-si (KR); Hwan-Sik LIM, Gunpo-si (KR)

(73) Assignee: SAMSUNG ELECTRONICS CO., LTD., Suwon-si (KR)

(21) Appl. No.: 13/241,824

(22) Filed: Sep. 23, 2011

(30) Foreign Application Priority Data
Nov. 24, 2010 (KR) 10-2010-0117565

(51) Int. Cl. H01L 21/60; H01L 21/768

(52) U.S. Cl. 438/613; 438/675; 257/E21.508; 257/E21.586

(57) ABSTRACT

Provided are a method for manufacturing a semiconductor package and a semiconductor package manufactured using the method. The method includes providing a substrate having a first region and a second region having a higher step difference than the first region, i.e., having a difference in height, forming a mask pattern having a first opening exposing a portion of the first region and a second opening exposing a portion of the second region on the substrate, forming first and second bump material films filling the first and second openings, respectively, and forming the first and second bumps by performing a reflow process on the first and second bump material films, wherein the first opening has a lower portion having the same width with the second opening and a top portion having a width greater than the second opening.

### CROSS-REFERENCE TO RELATED APPLICATION

This application claims priority from Korean Patent Application No. 10-2010-0117565 filed on Nov. 24, 2010 in the Korean Intellectual Property Office, and all the benefits accruing therefrom under 35 U.S.C. 119, the contents of which in its entirety are herein incorporated by reference.

### BACKGROUND

1. Field

The exemplary embodiments relate to a method for manufacturing a semiconductor package and a semiconductor package manufactured using the same, and more particularly to a method for manufacturing a semiconductor package having increased productivity and improved reliability, and a semiconductor package manufactured using the manufacturing method.

2. Description of the Related Art

In general, solder balls or bumps are formed as connecting terminals for electrically connecting a chip to another chip or a chip to a board in the manufacture of a semiconductor package.

A recent tendency for solving problems associated with the manufacture of a semiconductor package, including failures such as cracks occurring to the semiconductor package is to form dummy bumps functioning to support chips during a subsequent assembling process while not serving as electrical connection means, in addition to real bumps serving as electrical connection means, which is an intrinsic function of a bump.

A real bump is generally formed on a bonding pad while a dummy bump is formed on a protection layer positioned higher than the bonding pad. Therefore, when a real bump and a dummy bump are simultaneously formed, a top of the dummy bump is positioned higher than a top of the real bump by a step difference between the bonding pad and the protection layer.

If the tops of the real bump and the dummy bump are differently positioned, it is quite difficult to secure a processing margin in a subsequent assembling process, resulting in many failures. For example, in a subsequent assembling process, only a dummy bump may be opened while a real bump is not opened.

Accordingly, there is a need for developing the technique of forming a dummy bump and a real bump having tops positioned at the same height.

### SUMMARY

The exemplary embodiments provide a method for manufacturing a semiconductor package having increased productivity and improved reliability by reducing a top height difference between a dummy bump and a real bump without separately adding process steps.

The exemplary embodiments also provide a semiconductor package manufactured using the manufacturing method.

These and other aspects of the exemplary embodiments will be described in or be apparent from the following description.

According to an aspect of an exemplary embodiment, there is provided a method for manufacturing a semiconductor package including providing a substrate having a first region and a second region having a higher step difference than the first region, forming a mask pattern having a first opening exposing a portion of the first region and a second opening exposing a portion of the second region on the substrate, forming first and second bump material films filling the first and second openings, respectively, and forming the first and second bumps by performing a reflow process on the first and second bump material films, wherein the first opening has a bottom portion having the same width with the second opening and a top portion having a width greater than the second opening.

According to another aspect of an exemplary embodiment, there is provided a method for manufacturing a semiconductor package including providing a substrate having a first region and a second region having a higher step difference than the first region, forming a photoreist on the substrate, exposing and developing the photoresist using an exposure mask having a first transmissive region corresponding to a potential portion of a first bump in the first region, a semi-transmissive region surrounding the first transmissive region, and a second transmissive region corresponding to a potential portion of a second bump in the second region, and forming a photoresist pattern having a first opening corresponding to the potential portion of the first bump in the first region and a second opening corresponding to the potential portion of the second bump, forming first and second bump material films filling the first and second openings, respectively, and forming the first and second bumps by performing a reflow process on the first and second bump material films.

According to still another aspect of an exemplary embodiment, there is provided a semiconductor package including a substrate having a first region and a second region having a higher step difference than the first region, a first plating film formed on the first region, a second plating film formed on the second region and having the same thickness with the first plating film, a first solder formed on the first plating film, and a second solder formed on the second plating film and having a smaller thickness than the first solder.

In another exemplary embodiment, there is a method for manufacturing a semiconductor package including: providing a substrate including a first region having a first height and a second region having a second height that is higher than the first height; forming a mask pattern including a first opening and a second opening, the first opening exposing a portion of the first region and the second opening exposing a portion of the second region on the substrate; forming a first bump material film and a second bump material film at the first and the second openings, respectively; and forming a first bump and a second bump by performing a reflow process on the first and the second bump material films, wherein the first opening includes a lower portion and a top portion, the lower portion having a width that is the same as a width of the second opening and the top portion having a width that is greater than the width of the second opening.

In yet another exemplary embodiment, there is a method for manufacturing a semiconductor package including: providing a substrate including a first region having a first height and a second region having a second height that is higher than the first height; forming a photoreist on the substrate; exposing and developing the photoresist using an exposure mask having a first transmissive region corresponding to a portion for a first bump in the first region, a semi-transmissive region surrounding the first transmissive region, and a second transmissive region corresponding to a portion for a second bump in the second region, and forming a photoresist pattern having a first opening corresponding to the portion for the first bump in the first region and a second opening corresponding to the portion for the second bump; forming a first bump material film and a second bump material film at the first and the second openings, respectively; and forming the first and the second bumps by performing a reflow process on the first and the second bump material films.

In an exemplary embodiment, there is A semiconductor package including: a substrate including a first region of a first height and a second region of a second height that is higher than the first height of the first region; a first plating film of a first film thickness, formed on the first region; a second plating film of a second film thickness, formed on the second region, the first and the second film thicknesses being the same; a first solder of a first solder thickness formed on the first plating film; and a second solder of a second solder thickness formed on the second plating film, the second solder thickness being less than the first solder thickness.

In another exemplary embodiment, there is a method for manufacturing a semiconductor package including: providing a substrate including a first surface having a first surface height and a second surface having a second surface height that is higher than the first surface height; forming a mask over the substrate, the mask including a first opening and a second opening respectively disposed over the first and the second surfaces of the substrate, and a level top surface so that tops of the first and the second openings are at a same height; forming a first bump material film and a second bump material film at the first and the second openings, respectively; and forming a first bump and a second bump from the first and the second bump material films, wherein the first opening has a funnel shape such that a top portion of first opening tapers down to a width that is the same as a width of the second opening.

### BRIEF DESCRIPTION OF THE DRAWINGS

The above and other features and aspects of the exemplary embodiments will become more apparent by describing in detail exemplary embodiments thereof with reference to the attached drawings in which:

FIGS. 1A to 1F are cross sectional views showing process steps for explaining a method for manufacturing a semiconductor package according to an exemplary embodiment;

FIG. 2 is a plan view showing an exemplary mask used when performing the process shown in FIG. 1B;

FIGS. 3A and 3B are cross sectional views showing process steps for explaining a method for manufacturing a semiconductor package according to another exemplary embodiment; and

FIG. 4 is a photograph showing an exemplary experiment of a mask pattern formed as the result of performing the process shown in FIG. 1B.

### DETAILED DESCRIPTION

Aspects and features of the present invention and methods of accomplishing the same may be understood more readily by reference to the following detailed description of exemplary embodiments and the accompanying drawings. The present invention may, however, be embodied in many different forms and should not be construed as being limited to the exemplary embodiments set forth herein. Rather, these exemplary embodiments are provided so that this disclosure will be thorough and complete and will fully convey the concept of the invention to those skilled in the art, and the present invention will only be defined by the appended claims. In the drawings, the thickness of layers and regions are exaggerated for clarity.

It will be understood that when an element or layer is referred to as being “on,” or “connected to” another element or layer, it can be directly on or connected to the other element or layer or intervening elements or layers may be present. In contrast, when an element is referred to as being “directly on” or “directly connected to” another element or layer, there are no intervening elements or layers present. Like numbers refer to like elements throughout. As used herein, the term “and/or” includes any and all combinations of one or more of the associated listed items.

Spatially relative terms, such as “below,” “beneath,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

Exemplary embodiments described herein will be described referring to plan views and/or cross-sectional views by way of ideal schematic views of the invention. Accordingly, the exemplary views may be modified depending on manufacturing technologies and/or tolerances. Therefore, the exemplary embodiments of the invention are not limited to those shown in the views, but include modifications in configuration formed on the basis of manufacturing processes. Therefore, regions exemplified in figures have schematic properties and shapes of regions shown in figures exemplify specific shapes of regions of elements and not limit aspects of the invention.

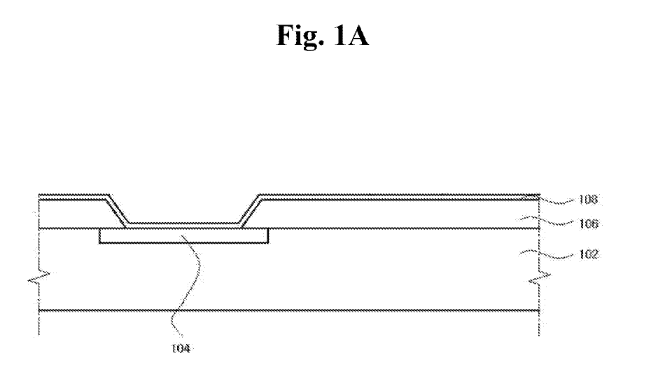

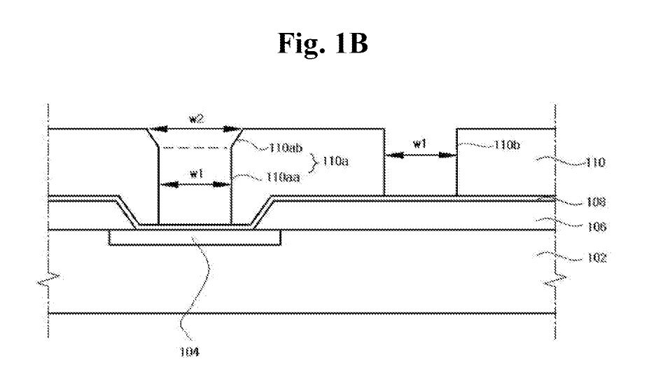

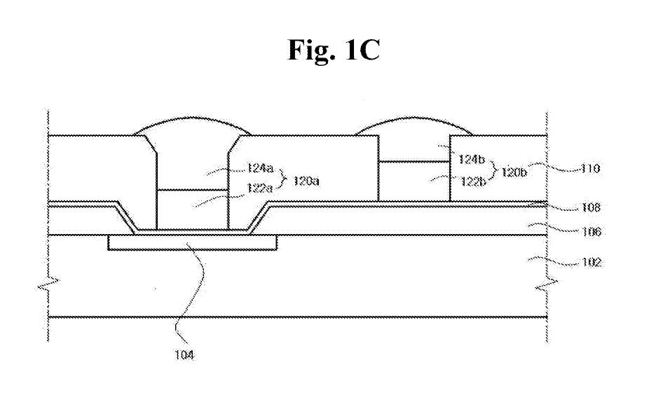

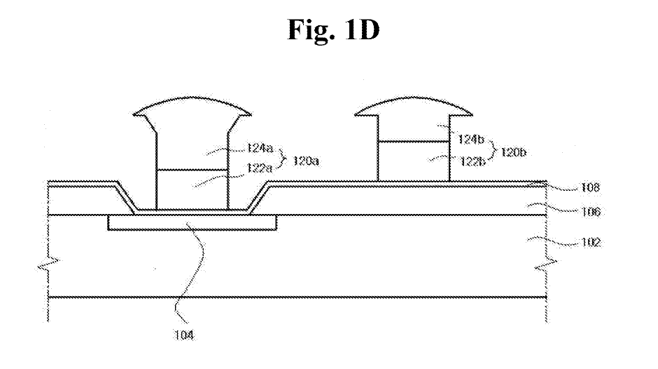

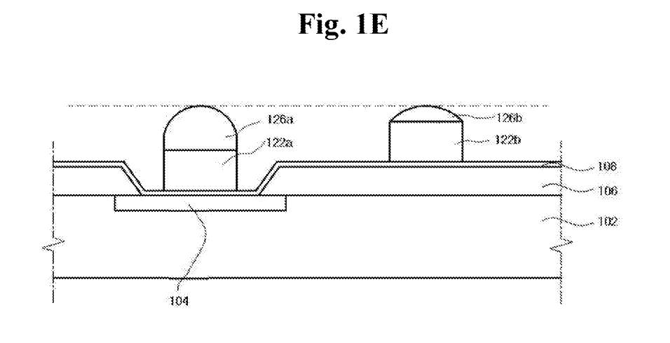

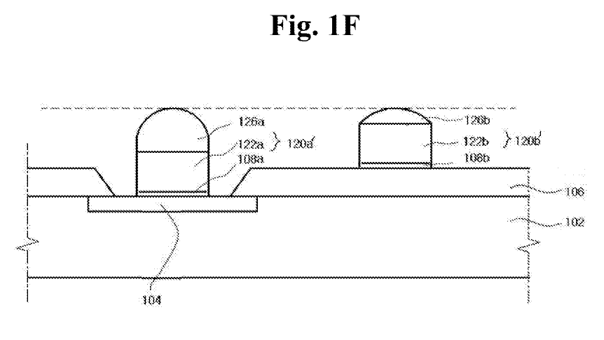

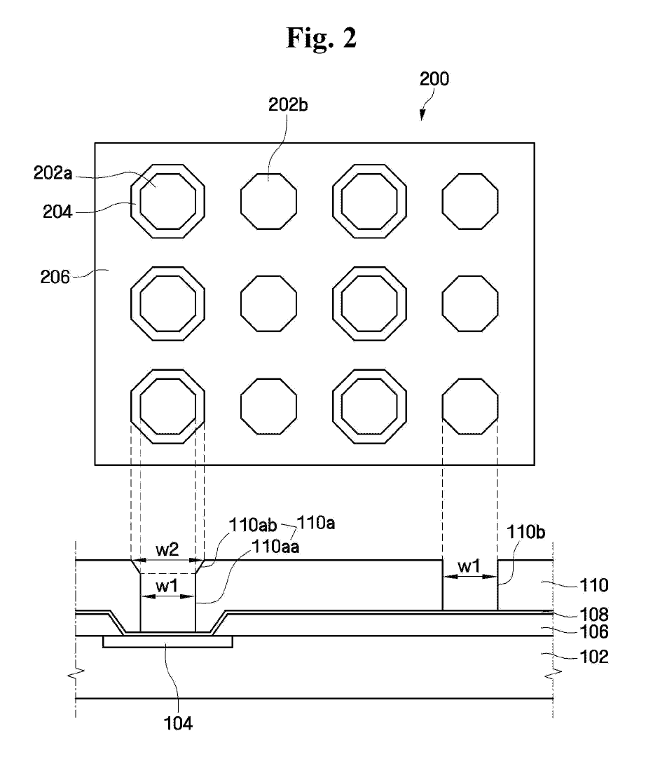

Hereinafter, a method for manufacturing a semiconductor package according to an exemplary embodiment will be described with reference to FIGS. 1A to 1F and FIG. 2. FIGS. 1A to 1F are cross sectional views showing process steps for explaining a method for manufacturing a semiconductor package according to an exemplary embodiment, and FIG. 2 is a plan view showing an exemplary mask used when performing the process shown in FIG. 1B, along with a side view of the same.

Referring to FIG. 1A, a substrate 102 is prepared. The substrate 102 may be a substrate in the unit of a wafer or a substrate in the unit of chips obtained by dividing a wafer into a plurality of parts. A circuit pattern may be formed in the substrate 102.

Next, a bonding pad 104 electrically connected to the circuit pattern and a protection layer 106 exposing a portion of the bonding pad 104 are formed on the substrate 102. The bonding pad 104 may be redistributed or distributed in the center or periphery of the substrate 102. In an exemplary embodiment, the bonding pad 104 may be made of a metal such as aluminum (Al), and the protection layer 106 may be made of an insulation material such as nitride, oxide or polyimide.

Since the protection layer 106 is formed on the bonding pad 104, a surface height of the protection layer 106 is greater than that of the bonding pad 104 from the viewpoint of the substrate 102. Therefore, there is a step difference, i.e., a difference in height, between a region where the protection layer 106 is formed, which will be referred to a second region, hereinafter, and a region where a portion of the bonding pad 104 is exposed due to the lack of the protection layer 106, which will be referred to a first region, hereinafter.

Next, a metal film 108 may further be formed on the entire surface of the substrate 102 having the bonding pad 104 and the protection layer 106. The metal film 108 may be an under bump metallurgy (UBM) functioning as an adhesive layer, a diffusion preventing layer and a wetting layer. The metal film 108 may be formed to have a multi-layered structure by depositing a variety of metals, including chromium (Cr), copper (Cu), nickel (Ni), titanium-tungsten (TiW), nickel-vanadium (NiV), and other similar metals, through sputtering. In an exemplary embodiment, the metal film 108 may have a structure of Cr/Cr—Cu/Cu, TiW/Cu, Al/NiV/Cu, or Ni/Au. The metal film 108 may be used as a seed layer in a subsequent plating process.

Referring to FIG. 1B, a mask pattern 110 having first and second openings 110a and 110b exposing potential bump regions is formed on the metal film 108. Here, the term “potential bump regions” encompasses both a region where a real bump functioning as electrical connection means is to be formed, and a region where a dummy bump not functioning as electrical connection means is to be formed. For convenience of explanation, it is assumed that the first opening 110a exposes a region where a real bump is to be formed, and the second opening 110b exposes a region where a dummy bump is to be formed. Therefore, the first opening 110a may be formed to expose a portion of the metal film 108 on the bonding pad 104, and the second opening 110b may be formed to expose a portion of the metal film 108 on the protection layer 106.

Here, the second opening 110b has a predetermined width, and the first opening 110a consists of a lower portion 110aa having a predetermined width and a top portion 110ab integrally connected to the lower portion 110aa and having a greater width than the lower portion 110aa. In another exemplary embodiment, the lower portion 110aa may be a bottom portion. Here, the width of the lower portion 110aa of the first opening 110a may be the same width (refer to reference symbol W1) as the second opening 110b. That is to say, the top portion 110ab of the first opening 110a has width W2 that is greater than the width W1 of the lower portion 110aa of the first opening 110a and the width W1 of the second opening 110b.

In this exemplary embodiment, the top portion 110ab of the first opening 110a is shaped such that its width gradually increases from the lower to the top. In this case, the top portion 110ab of the first opening 110a has the greatest width at its topmost portion, which is denoted by reference symbol W2, but the exemplary embodiments are not limited thereto. The top portion 110ab of the first opening 110a may have a variety of shapes on the assumption that it has a width greater than the width W1 of the lower portion 110aa of the first opening 110a and the width W1 of the second opening 110b.

Meanwhile, the mask pattern 110 may be a photoresist pattern formed by coating a photoresist and exposing and developing the same. Here, a mask having a semi-transmissive region is used in the exposing step, thereby forming the mask pattern 110 having first and second openings 110a and 110b having the above-described shapes, which will now be described with reference to FIGS. 1B and 2.

First, photoresist (not shown) is coated on the metal film 108. Here, the photoresist may be a positive type.

Next, an exposing process is performed using an exposure mask 200 shown in FIG. 2.

The exposure mask 200 will now be described in more detail. The exposure mask 200 has first and second transmissive regions 202a and 202b, a semi-transmissive region 204, and a shielding region 206. Here, the term “semi-transmissive region 204” means a region where light is not completely transmitted and is not completely shielded during the exposing process. The transmittance of light in the semi-transmissive region 204 may be in a range of, for example, 30% to 50%.

Here, the first transmissive region 202a and the semi-transmissive region 204 are used to form the first opening 110a, and the second transmissive region 202b is used to form the second opening 110b. In detail, the first transmissive region 202a is disposed to correspond to the lower portion 110aa of the first opening 110a, and the semi-transmissive region 204 is disposed to have a predetermined width while surrounding the first transmissive region 202a. Here, the predetermined width is substantially the same as a value obtained by subtracting the width W1 of the lower portion 110aa of the first opening 110a from the width W2 of the topmost portion of the first opening 110a. In addition, the second transmissive region 202b is disposed to correspond to the second opening 110b.

The developing process is performed after performing the exposing process using the exposure mask 200. As the result, the photoresist corresponding to the first and second transmissive regions 202a and 202b does not remain but is completely removed, while the photoresist corresponding to the shielding region 206 is not removed but remains thick. The photoresist corresponding to the semi-transmissive region 204 remains thinner than the photoresist corresponding to the shielding region 206. As the result, as shown in FIGS. 1B and 2, the mask pattern 110 can be formed, the mask pattern 110 having the first opening 110a having top and lower portions with different profiles or cross sectional shapes and the second opening 110b having a single profile or a single cross sectional shape.

Since the mask pattern 110 having the first and second openings 110a and 110b can be formed simply by adjusting the mask used for exposure through the above-described process, it is possible to form the first and second openings 110a and 110b having different profiles without separately adding process steps.

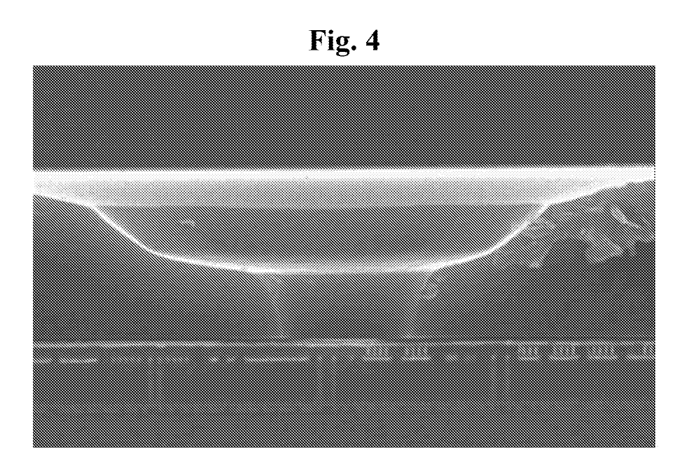

The use of the above-described exposure mask 200 allows the first opening 110a having the top and lower portions with different profiles, to be formed, which is illustrated in the exemplary experiment shown in FIG. 4.

FIG. 4 is a photograph showing an exemplary experiment of a mask pattern formed as the result of performing the process shown in FIG. 1B, in which a photoresist pattern is illustrated, the photoresist pattern obtained after exposing photoresist using an exposure mask having a transmissive region having a substantially circular shape and developing the same.

Referring to FIG. 4, photoresist does not remain on a portion of the exposure mask, corresponding to a transmissive region, while a thin amount of the photoresist remains on a portion of the exposure mask, corresponding to a semi-transmissive region, thereby forming a photoresist pattern having double profiles of a lower portion having a predetermined width and a top portion having a width that increases in width with height. In an exemplary embodiment, the width of the top portion tapers down to the smaller width of the lower portion. In another exemplary embodiment, the top portion may be taper down at multiple different angles or curves to the lower portion. In an exemplary embodiment, the first opening has a funnel shape.

In the exposure mask 220 according to the illustrated embodiment, a plurality of first transmissive regions 202a for forming a first opening 110a and a plurality of semi-transmissive regions 204 surrounding the first transmissive regions 202a are arranged columnwise, a plurality of columns of the first transmissive regions 202a and a plurality of columns of the semi-transmissive regions 204 surrounding the first transmissive regions 202a are arranged rowwise. In addition, a plurality of second transmissive regions 202b for forming a second opening 110b and a plurality of columns of second transmissive region 202b are arranged rowwise. Here, the first transmissive regions 202a, the columns of the semi-transmissive regions 204 surrounding the first transmissive regions 202a and the columns of the second transmissive regions 202b may be alternatingly arranged columnwise.

Therefore, although not shown in FIGS. 1A to 1F, a plurality of first openings 110a are arranged columnwise, columns of the first openings 110a are arranged rowwise, a plurality of second openings 110b are arranged columnwise, and columns of the second openings 110b are arranged rowwise. Further, the columns of the first openings 110a and the columns of the second opening 110b are alternatingly arranged. However, the exemplary embodiments are not limited thereto, and the number or arrangement of the first and second openings 110a and 110b may be changed in various manners.

Referring to FIG. 1C, after performing the process shown in FIG. 1B, first and second bump material films 120a and 120b respectively filling in the first and second openings 110a and 110b are formed. Here, the first and second bump material films 120a and 120b may include a dual layer including a conductive layer and a conductive paste stacked. Here, the conductive layer may be a plating film formed by a plating process, and the conductive paste may be a solder paste or a metal paste, but not limited thereto. In this exemplary embodiment, the first bump material film 120a may have a stack of a first plating film 122a and a first solder paste 124a, and the second bump material film 120b may have a stack of a second plating film 122b and a second solder paste 124b. A method of forming the first and second bump material films 120a and 120b will now be described in more detail.

First, the plating film is grown by electroplating using the metal film 108 as a seed layer, thereby forming the first and second first plating films 122a and 122b completely or partially filling in the first opening 110a. In this exemplary embodiment, the first and second plating films 122a and 122b fill in the first and second openings 110a and 110b in part, but the exemplary embodiments are not limited thereto. The first and second plating films 122a and 122b may substantially completely fill in the first and second openings 110a and 110b. The first and second plating films 122a and 122b may be made of a variety of metals such as nickel (Ni), copper (Cu), palladium (Pd), platinum (Pt), gold (Au), combinations thereof, or the like.

Next, first and second solder pastes 124a and 124b are formed on the first and second plating films 122a and 122b, respectively. The first and second solder pastes 124a and 124b may be formed by a stencil process or an inkjet printing process. As in this exemplary embodiment, in a case where the first and second plating films 122a and 122b partially fill in the first and second openings 110a and 110b, the formed mask pattern 110 may be used as a mask pattern for forming the first and second solder pastes 124a and 124b. In contrast, in a case where the first and second plating films 122a and 122b completely fill in the first and second openings 110a and 110b, an additional mask pattern may be required to form the first and second solder pastes 124a and 124b.

As described above, the top portion 110ab of the first opening 110a has a width that is greater than its lower portion 110aa and the second opening 110b. Therefore, when performing the process shown in FIG. 1C, an amount of the first bump material film 120a filling in the first opening 110a is greater than that of the second bump material film 120b filling in the second opening 110b. In more detail, if the first and second plating films 122a and 122b partially fill in the first and second openings 110a and 110b, an amount of the first solder paste 124a filling in the first opening 110a is greater than that of the second solder paste 124b filling in the second opening 110b. If the first and second plating films 122a and 122b completey fill in the first and second openings 110a and 110b, an amount of the first plating film 122a filling in the first opening 110a is greater than that of the second plating film 122b filling in the second opening 110b. This reduces a top height difference between first and second bumps formed in a subsequent reflow process, which will later be described in more detail.

Referring to FIG. 1D, the mask pattern 110 is removed. In a case where the mask pattern 110 is formed of photoresist, the removing of the mask pattern 110 may be performed by, for example, an aching process using oxygen.

As the result of removing the mask pattern 110, the first and second bump material films 120a and 120b having substantially mushroom-like shapes remain on the substrate 102.

Referring to FIG. 1E, the reflow process is performed on the first and second bump material films 120a and 120b, specifically, the first and second solder pastes 124a and 124b, thereby forming first and second solders 126a and 126b having substantially hemispherical or domed shapes.

As described above, the amount of the first solder paste 124a filling in the first opening 110a is greater than that of the second solder paste 124 filling in the second opening 110b. Thus, a thickness of the first solder 126a is greater than that of the second solder 126b, thereby compensating for a bottom step difference, i.e., the difference in height between the bottoms or the bases, of the first and the second plating films 122a and 122b. Thus, the tops of the first solder 126a and a top height of the second solder 126b are substantially at the same height. That is to say, a topmost portion of the first solder 126a and a topmost portion of the second solder 126b are aligned in a line (see dotted line).

Referring to FIG. 1F, the metal film 108 exposed by the first and second plating films 122a and 122b is removed by etching, thereby forming a first metal film pattern 108a disposed under the first plating film 122a and a second metal film pattern 108b disposed under the second plating film 122b.

As the result of performing the process illustrated, a first bump 120a′ electrically connected to the bonding pad 104, has a stacked arrangement of the first metal film pattern 108a, the first plating film 122a and the first solder 126a, and is formed on the bonding pad 104, and a second bump 120b′ insulated from the substrate 102, has a stacked arrangement of the second metal film pattern 108b, the second plating film 122b and the second solder 126b, and is disposed on the protection layer 106. Here, the first bump 120a′ functions as a real bump, and the second bump 120b′ functions as a dummy bump.

The first plating film 122a and the second plating film 122b may have the same thickness. However, the second solder 126b may have a smaller thickness than the first solder 126a. Accordingly, a top portion of the first solder 126a may be positioned on the same line with a top portion of the second solder 126b. That is to say, a step difference or height difference between the first region having the bonding pad 104 exposed and the second region having the protection layer 106 is compensated for, so that the top portion of the first solder 126a and the top portion of the second solder 126b are positioned at substantially the same height. As the result, a height difference between the top portions the first bump 120a′ and the second bump 120b′ can be reduced.

As described above, when the first and second openings 110a and 110b are disposed, a plurality of first bumps 120a′ are disposed columnwise, and a plurality of columns of the first bumps 120a′ may be arranged rowwise. In addition, a plurality of second bumps 120b′ are disposed columnwise, and a plurality of columns of the second bump 120b′ may be arranged rowwise. Further, each of the columns of the first bumps 120a′ may be alternatingly disposed with each of the columns of the second bumps 120b′, i.e., interleaved with each other. However, the exemplary embodiments do not limit the number and arrangement method of each of the first bumps 120a′ and the second bumps 120b′ to those illustrated herein, and the number and arrangement method of each of the first bumps 120a′ and the second bumps 120b′ may be changed in various manners.

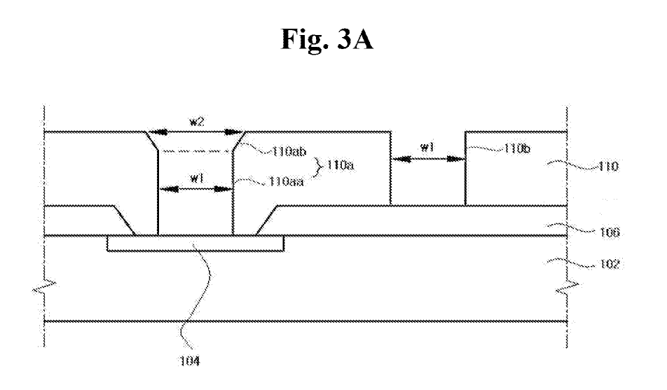

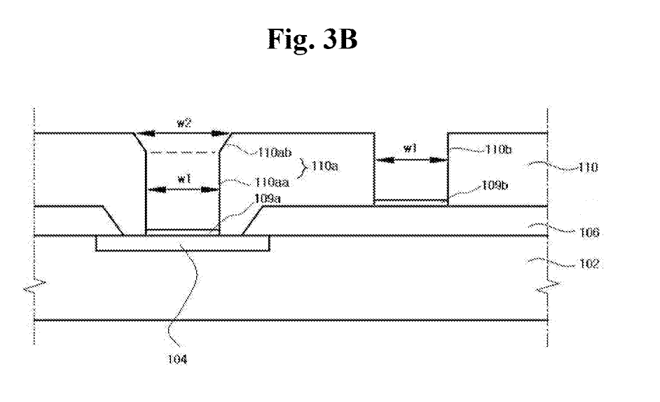

Next, a method for manufacturing a semiconductor package according to another exemplary embodiment will be described with reference to FIGS. 3A and 3B. FIGS. 3A and 3B are cross sectional views showing process steps for explaining a method for manufacturing a semiconductor package according to another exemplary embodiment. In the following description, repeated explanations will not be given or will be briefly given because the illustrated exemplary embodiment is substantially the same as the previous exemplary embodiment except that a mask pattern 110 is first formed and a metal film 108 is then formed.

Referring to FIG. 3A, a substrate 102 is prepared. A bonding pad 104 electrically connected to a circuit pattern and a protection layer 106 exposing a portion of the bonding pad 104 are formed on the substrate 102.

Next, a mask pattern 110 having first and second openings 110a and 110b exposing potential bump regions is formed on the substrate 102 having the bonding pad 104 and the protection layer 106. Here, the first opening 110a exposes a portion of the bonding pad 104, and the second opening 110b exposes a portion of the protection layer 106.

Referring to FIG. 3B, a first metal film pattern 109a and a second metal film pattern 109b are formed on the bonding pad 104 and the protection layer 106 exposed by the first and second openings 110a and 110b, respectively. The first metal film pattern 109a and the second metal film pattern 109b are made of substantially the same material as that of the metal film 108 in the previous exemplary embodiment and may be used as seed layers in a subsequent plating process.

As described above, since the mask pattern 110 is first formed and the first and second metal film patterns 109a and 109b are formed in the first and second openings 110a and 110b, respectively, the process of etching the metal film 108 shown in FIG. 1F may be omitted.

After performing the process shown in FIG. 3B, the processes shown in FIGS. 1C to 1E are sequentially performed, thereby forming a real bump and a dummy bump. The real bump is electrically connected to the bonding pad 104 and has a stacked arrangement of the first metal film pattern 109a, the first plating film 122a and the first solder 126a. The dummy bump is positioned on the protection layer 106 while being insulated from the substrate 102, and has the second metal film pattern 109b, the second plating film 122b and the second solder 126b stacked.

While the present invention has been particularly shown and described with reference to exemplary embodiments thereof, it will be understood by those of ordinary skill in the art that various changes in form and details may be made therein without departing from the spirit and scope of the present invention as defined by the following claims. It is therefore desired that the present exemplary embodiments be considered in all respects as illustrative and not restrictive, reference being made to the appended claims rather than the foregoing description to indicate the scope of the invention.

1. A method for manufacturing a semiconductor package comprising:
providing a substrate comprising a first region having a first height and a second region having a second height that is higher than the first height;
forming a mask pattern comprising a first opening and a second opening, the first opening exposing a portion of the first region and the second opening exposing a portion of the second region on the substrate;
forming a first bump material film and a second bump material film at the first and the second openings, respectively; and
forming a first bump and a second bump by performing a reflow process on the first and the second bump material films,
wherein the first opening comprises a lower portion and a top portion, the lower portion having a width that is the same as a width of the second opening and the top portion having a width that is greater than the width of the second opening.

2. The method of claim 1, wherein the first region is a region where a bonding pad is disposed, and the second region is a region where a protection layer exposing the bonding pad is disposed.

3. The method of claim 2, wherein the first bump is electrically connected to the bonding pad and is of a plurality of first bumps arranged in a first direction to form a first column in the first direction; the second bump is disposed on the protection layer and is of a plurality of second bumps arranged in the first direction to form a second column in the first direction; and the first column is of a plurality of first columns and the second column is of a plurality of second columns, the plurality of first and the plurality of second columns being alternatingly disposed along a second direction crossing the first direction.

4. The method of claim 1, wherein the forming of the mask pattern comprises:
forming a photoresist on the substrate; and
exposing and developing the photoresist using an exposure mask having a first transmissive region corresponding to the lower portion of the first opening, a semi-transmissive region corresponding to a portion of the first opening which is defined by excluding the lower portion of the first opening from the top portion of the first opening while surrounding the first transmissive region, and a second transmissive region corresponding to the second opening.

5. The method of claim 1, wherein each of the lower portion of the first opening and the second opening has a predetermined width, and a width of the top portion of the first opening gradually increases from a bottom to a top of the top portion.

6. The method of claim 1, wherein the forming of the first and the second bump material films comprises:
forming a first conductive film and a second conductive film which partially or completely fill in the first and the second openings, respectively; and
forming a first conductive paste and a second conductive paste on the first and the second conductive films, respectively.

7. The method of claim 6, wherein the forming of the first and the second conductive films is performed by plating.

8. The method of claim 7, after the providing of the substrate, further comprising forming a metal film on an entire surface of the substrate, wherein the forming of the first and the second conductive films is performed by electroplating using the metal film as a seed layer.

9. The method of claim 7, after the forming of the mask pattern, further comprising forming metal film patterns on the substrate exposed by the first opening and the second opening, respectively, wherein the forming of the first and the second conductive films is performed by electroplating using the metal film pattern as a seed layer.

10. The method of claim 1, after the forming of the first and the second bump material films, further comprising removing the mask pattern.

11. A method for manufacturing a semiconductor package comprising:
providing a substrate comprising a first region having a first height and a second region having a second height that is higher than the first height;
forming a photoreist on the substrate;
exposing and developing the photoresist using an exposure mask having a first transmissive region corresponding to a portion for a first bump in the first region, a semi-transmissive region surrounding the first transmissive region, and a second transmissive region corresponding to a portion for a second bump in the second region, and forming a photoresist pattern having a first opening corresponding to the portion for the first bump in the first region and a second opening corresponding to the portion for the second bump;
forming a first bump material film and a second bump material film at the first and the second openings, respectively; and
forming the first and the second bumps by performing a reflow process on the first and the second bump material films.

12. The method of claim 11, wherein the first region is a region where a bonding pad is disposed, and the second region is a region where a protection layer exposing the bonding pad is disposed.

13. The method of claim 12, wherein the first bump is electrically connected to the bonding pad and is of a plurality of first bumps arranged in the first direction to form a first column in the first direction; the second bump is disposed on the protection layer and is of a plurality of second bumps arranged in the first direction to form a second column in the first direction; and the first column is of a plurality of first columns and the second column is of a plurality of second columns, the plurality of first and the plurality of second columns being alternatingly disposed along a second direction crossing the first direction.

14. The method of claim 11, wherein the first opening has a lower portion and a top portion, the lower portion having a width that is the same as a width of the second opening and the top portion having a width that is greater than the width of the second opening.

15. The method of claim 14, wherein each of the lower portion of the first opening and the second opening has a predetermined width, and a width of the top portion of the first opening gradually increases from a bottom to a top of the top portion.

16. The method of claim 11, wherein the forming of the first and the second bump material films comprises:
forming a first conductive film and a second conductive film which partially or completely fill in the first and the second openings, respectively; and
forming a first conductive paste and a second conductive paste on the first and the second conductive films, respectively.

17. (canceled)

18. The method of claim 16, wherein the forming of the first and the second conductive films is performed by plating, and
after the providing of the substrate, further comprising forming a metal film on an entire surface of the substrate, wherein the forming of the first and the second conductive films is performed by electroplating using the metal film as a seed layer.

19. The method of claim 16, wherein the forming of the first and the second conductive films is performed by plating, and
after the forming of the photoresist pattern, further comprising forming metal film patterns on the substrate exposed by the first opening and the second opening, respectively, wherein the forming of the first and the second conductive films is performed by electroplating using the metal film pattern as a seed layer.

20. (canceled)

21. (canceled)

22. (canceled)

23. A method for manufacturing a semiconductor package comprising:
providing a substrate comprising a first surface having a first surface height and a second surface having a second surface height that is higher than the first surface height;
forming a mask over the substrate, the mask comprising a first opening and a second opening respectively disposed over the first and the second surfaces of the substrate, and a level top surface so that tops of the first and the second openings are at a same height;
forming a first bump material film and a second bump material film at the first and the second openings, respectively; and
forming a first bump and a second bump from the first and the second bump material films,
wherein the first opening has a funnel shape such that a top portion of first opening tapers down to a width that is the same as a width of the second opening.

24. The method of claim 19, wherein tops of the first and the second bumps are at a same bump height.
